(19) United States
(12) Patent Application Publication
(10) Pub. No.: US 2026/0005071 A1
(43) Pub. Date: Jan. 1, 2026

(54) SEMICONDUCTOR MANUFACTURING METHOD USING WARPAGE DEFORMATION

(71) Applicant: Samsung Electronics Co., Ltd., Suwon-si (KR)

(72) Inventors: Jinyoung LEE, Suwon-si (KR); Sunghyup KIM, Suwon-si (KR)

(21) Appl. No.: 18/966,769

(22) Filed: Dec. 3, 2024

(30) Foreign Application Priority Data
Jun. 26, 2024 (KR) 10-2024-0083512

(51) Int. Cl. H01L 21/66; H01L 21/683

(52) U.S. Cl. CPC H01L 22/12; H01L 21/6831

(57) ABSTRACT

A semiconductor manufacturing method using warpage deformation includes thermally deforming a three-dimensional warpage of a wafer into a two-dimensional warpage of the wafer by adjusting a temperature of each area of a plurality of areas of a stage where the wafer is mounted, chucking the wafer when the three-dimensional warpage of the wafer has been deformed into the two-dimensional warpage of the wafer, and performing a semiconductor process while the wafer is chucked.

### CROSS-REFERENCE TO RELATED APPLICATION(S)

This application claims the priority benefit of Korean Patent Application No. 10-2024-0083512 filed on Jun. 26, 2024, in the Korean Intellectual Property Office, the disclosure of which is incorporated herein by reference for all purposes.

### BACKGROUND

### 1. Field

The following description relates to a semiconductor manufacturing method using warpage deformation.

### 2. Description of Related Art

Thermal and/or mechanical stress during the manufacturing process of semiconductor dies or semiconductor packages may cause warpage problems. Semiconductor warpage problems may have a significant impact on the performance and reliability of semiconductor products. For example, semiconductor warpages may cause mechanical defects, like cracks or delamination, or the deterioration of device features. In addition, if a semiconductor warpage exceeds facility tolerance, it becomes difficult to chuck a wafer and perform the process. The above description is information the inventor(s) acquired during the course of conceiving the present disclosure, or already possessed at the time, and is not necessarily art publicly known before the present application was filed.

### SUMMARY

According to some embodiments, a semiconductor manufacturing method using warpage deformation includes thermally deforming a three-dimensional warpage of a wafer into a two-dimensional warpage of the wafer by adjusting a temperature of each area of a plurality of areas of a stage where the wafer is mounted, chucking the wafer when the three-dimensional warpage of the wafer has been deformed into the two-dimensional warpage of the wafer, and performing a semiconductor process while the wafer is chucked.

According to some embodiments, in the thermally deforming, the stage may be heated or cooled such that a temperature of a first area of the plurality of areas of the stage, overlapping a portion of the wafer having a crying warpage shape is higher than a temperature of a second area of the plurality of areas of the stage overlapping another portion of the wafer having a smile warpage shape.

According to some embodiments, the semiconductor manufacturing method may further include receiving warpage information of the wafer. The thermally deforming may include determining a target temperature of each area of the plurality of areas of the stage and a deformation time of each area of the plurality of areas, based on the warpage information, and driving at least one temperature controller installed in the stage, based on the determined target temperature of each area of the plurality of areas and the determined deformation time of each area of the plurality of areas.

According to some embodiments, the warpage information may include warpage shape information of each area of a plurality of areas of the wafer overlapping corresponding areas of the plurality of areas of the stage and deviation information for a reference plane of each area of the plurality of areas of the wafer. The target temperature of each area of the plurality of areas of the stage may be set based on the warpage shape information of each area of the plurality of areas of the wafer. The deformation time of each area overlapping corresponding areas of the plurality of areas of the stage may be set to be longer as a deviation for the reference plane is greater.

According to some embodiments, the warpage information may include warpage shape information of each area of the plurality of areas of the wafer and deviation information for a reference plane. The target temperature of each area of the plurality of areas of the stage and the deformation time of each area of the stage may be determined based on which warpage type a warpage of the wafer belongs to among warpage types classified according to the warpage information.

According to some embodiments, the semiconductor manufacturing method may further include measuring warpage information of the wafer, determining whether the warpage shape of the wafer is a two-dimensional warpage shape, based on the warpage information, and outputting whether the warpage shape of the wafer is a two-dimensional warpage shape to a manager.

According to some embodiments, the semiconductor manufacturing method may further include measuring warpage information of the wafer and determining whether the warpage shape of the wafer is a two-dimensional warpage shape, based on the warpage information. If the warpage shape of the wafer is not a two-dimensional warpage shape, the thermally deforming is performed again based on the measured warpage information

According to some embodiments, the semiconductor manufacturing method may further include determining whether a deviation of a warpage of the wafer for a reference plane is less than a set value. The chucking of the wafer may be performed when the deviation of the warpage for the reference plane is less than the set value.

According to some embodiments, the semiconductor manufacturing method may further include decreasing a deviation of a two-dimensional warpage of the wafer for the reference plane by heating or cooling the stage by each area of the plurality of areas of the stage, based on the warpage information of the wafer.

According to some embodiments, in the thermally deforming, an area of the plurality of areas of the stage, vertically overlapping at least one sub-area of a first sub-area and a second sub-area, of the stage may be heated or cooled such that a calorie change per unit volume in the first sub-area, having a first radius of curvature, of the first area is greater than a calorie change per unit volume in the second sub-area, having a second radius of curvature greater than the first radius of curvature, of the first area.

According to some embodiments, in the thermally deforming, a temperature in the first sub-area and a temperature in the second sub-area may be set differently.

According to some embodiments, in the thermally deforming, a time for heating or cooling the first sub-area and a time for heating or cooling the second sub-area may be set independently.

According to some embodiments, in the thermally deforming, a first time for heating or cooling the first sub-area may be set to be greater than a second time for heating or cooling the second sub-area, in which at least some of the first time overlaps the second time.

According to some embodiments, the stage may include at least one adsorber for adsorbing the wafer to each area and may be a chuck for chucking the wafer by being installed in a facility for performing the semiconductor process.

According to some embodiments, in the chucking of the wafer, the adsorption power of the adsorber may increase as an area has a greater deviation of the wafer for a reference plane.

According to some embodiments, the thermally deforming may include a first thermal deformation for heating or cooling two areas of the plurality of areas of the stage spaced apart from each other in an angular direction at a temperature different from a temperature of the two other areas of the plurality of areas of the stage.

According to some embodiments, the thermally deforming may further include a second thermal deformation for heating or cooling four areas of the plurality of areas of the stage that are spaced apart from one another in an angular direction at a temperature different from a temperature of four other areas of the plurality of areas of the stage.

According to some embodiments, the thermally deforming may further include the second thermal deformation for decreasing a deviation of a two-dimensional warpage of the wafer for a reference plane by heating or cooling at least one area of the plurality of areas of the stage, and the plurality of areas of the stage are divided in a radial direction.

According to some embodiments, a semiconductor manufacturing method using warpage deformation includes thermally deforming a first area, having a crying warpage shape, of a wafer and a second area, having a smile warpage shape, of the wafer to be deformed into a warpage shape of the other area by adjusting a temperature of each area of a stage where the wafer is mounted, chucking the wafer when both the first area and the second area of the wafer have been deformed into the shape of the other of the first area or the second area, and performing a semiconductor process while the wafer is chucked.

According to some embodiments, a semiconductor manufacturing method using warpage deformation includes thermally deforming a first area, having a crying warpage shape, of a wafer and a second area, having a smile warpage shape, of the wafer to be deformed into the shape of the other area by adjusting a temperature of each area of the first area or the second area of a stage where the wafer is mounted, chucking the wafer when a deviation of a warpage of the wafer for a reference plane is less than a set value, and performing a semiconductor process while the wafer is chucked.

### BRIEF DESCRIPTION OF THE DRAWINGS

FIG. 1 is a conceptual diagram illustrating a system for warpage deformation, according to an embodiment.

FIG. 2 is a block diagram illustrating the system for warpage deformation, according to an embodiment.

FIG. 3 is a diagram illustrating a three-dimensional warpage in a saddle shape.

FIG. 4 is a diagram illustrating a two-dimensional warpage in an arch shape that is convex downwardly.

FIG. 5 is a diagram illustrating a two-dimensional warpage in an arch shape that is convex upwardly.

FIG. 6 is a flowchart illustrating a semiconductor manufacturing method using warpage deformation, according to an embodiment.

FIG. 7 is a side view of a system for warpage deformation, according to an embodiment.

FIG. 8 is a side view of a system for warpage deformation, according to an embodiment.

FIG. 9 is a block diagram illustrating a semiconductor process facility, including a system for warpage deformation, and a measuring facility, according to an embodiment.

FIG. 10 is a flowchart illustrating a method of adjusting a temperature of each area of a stage, according to an embodiment.

FIG. 11 is a table showing warpage information according to an embodiment.

FIG. 12 is a top view of a wafer and a stage, showing a method of adjusting a temperature of each area of the stage, according to an embodiment.

FIG. 13 is a top view of a wafer and a stage, showing a method of adjusting a temperature of each area of the stage, according to an embodiment.

FIG. 14 is a table showing warpage types according to an embodiment.

FIG. 15 is a flowchart illustrating a method of determining a target temperature of each area of the stage and a deformation time of each area of the stage, according to an embodiment.

FIG. 16 is a table representing the warpage information according to an embodiment.

FIG. 17 is a side view of deformation of a three-dimensional warpage into a two-dimensional warpage through a semiconductor manufacturing method using warpage deformation, according to an embodiment.

FIG. 18 is a top view of divided areas of a stage, according to an embodiment.

FIG. 19 is a diagram illustrating a method of varying target temperatures depending on areas of a stage, according to an embodiment.

FIG. 20 is a diagram illustrating a method of varying deformation times depending on areas of a stage, according to an embodiment.

FIG. 21 is a diagram illustrating a method of varying deformation times depending on areas of a stage, according to an embodiment.

FIG. 22 is a flowchart illustrating a semiconductor manufacturing method using warpage deformation, according to an embodiment.

FIG. 23 is a top view of a stage, showing divided areas, according to an embodiment.

FIG. 24 is a diagram illustrating a method of varying deformation times depending on areas of a stage, according to an embodiment.

### DETAILED DESCRIPTION

Hereinafter, embodiments are described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

As used herein, “A or B,” “at least one of A and B,” “at least one of A or B,” “A, B or C,” “at least one of A, B and C,” and “at least one of A, B, or C,” each of which may include any one of the items listed together in the corresponding one of the phrases, or all possible combinations thereof.

Unless otherwise defined, all terms including technical and scientific terms used herein have the same meaning as commonly understood by one of ordinary skill in the art to which embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like constituent elements and a repeated description related thereto will be omitted. In the description of embodiments, detailed description of well-known related structures or functions will be omitted when it is deemed that such description will cause ambiguous interpretation of the present disclosure.

In addition, terms such as first, second, A, B, (a), (b), and the like may be used to describe components of the embodiments. These terms are used only for the purpose of discriminating one constituent element from another constituent element, and the nature, the sequences, or the orders of the constituent elements are not limited by the terms. When one constituent element is described as being “connected”, “coupled”, or “attached” to another constituent element, it should be understood that one constituent element can be connected or attached directly to another constituent element, and an intervening constituent element can also be “connected”, “coupled”, or “attached” to the constituent elements.

A component, which has the same common function as a component included in any one embodiment, will be described by using the same name in other embodiments. Unless disclosed to the contrary, the configuration disclosed in any one embodiment may be applied to other embodiments, and the specific description of the repeated configuration will be omitted.

A wafer stage may be a chuck or plate on which a semiconductor wafer is securely mounted during wafer processing. Any suitable technique for chucking a wafer to secure the wafer to a wafer chuck may be used, including applying a vacuum to the backside of the wafer, such as by using an adsorber or adsorption unit to apply the vacuum to the backside of the wafer, or electrostatically securing the wafer to the chuck.

When a warpage of a wafer occurs, the warped wafer may have a shape curved upwardly with the edges bending downward, which is referred to as a cry or crying warpage shape, or the warped wafer may have a shape curved upwardly with the edges bending upwards, which is referred to as a smile or smiling warpage shape.

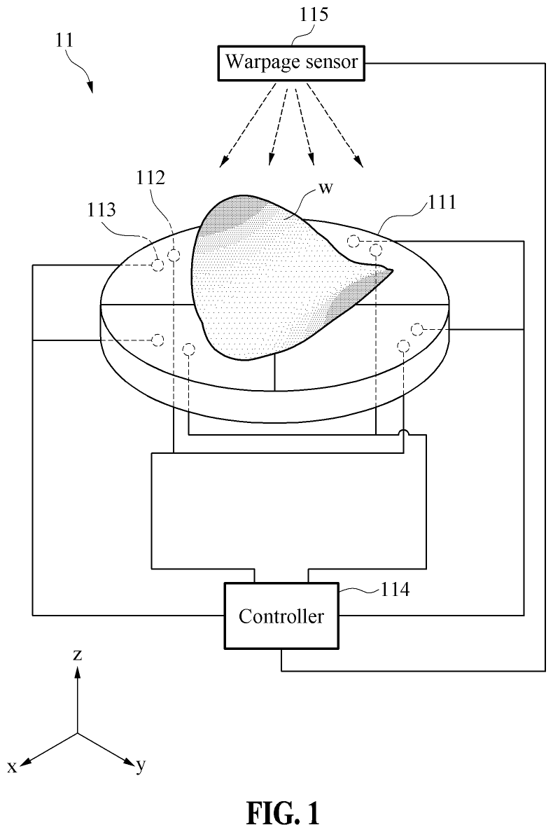

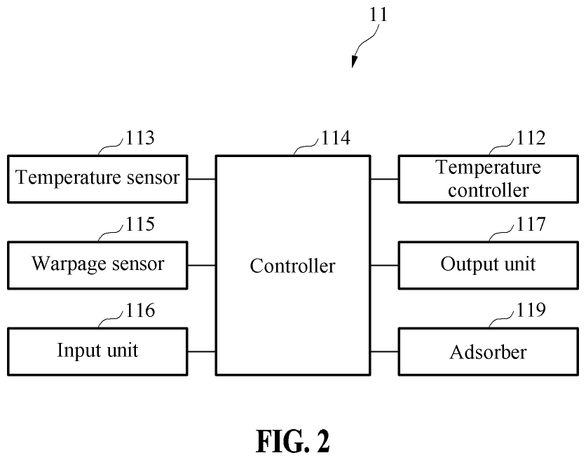

FIG. 1 is a conceptual diagram illustrating a system for warpage deformation, according to an embodiment, and FIG. 2 is a block diagram illustrating the system for warpage deformation, according to an embodiment.

Referring to FIGS. 1 and 2, a system 11 for warpage deformation, according to an embodiment, may deform a warpage in a wafer w by adjusting a temperature of each area of a stage 111 where the wafer w is mounted. Through this deformation, the wafer w may be deformed such that chucking, which has previously been impossible or difficult, may be performed. Thus, the performance and/or yield of semiconductor products may be improved. The system 11 for warpage transformation may include the stage 111, a temperature controller 112, a temperature sensor 113, a controller 114, a warpage sensor 115, an input unit 116, and an output unit 117.

At least one temperature controller 112 may be installed in the stage 111 and may control the temperature of the stage 111. At least some of the plurality of temperature controller 112 may be controlled independently of the others. For example, all the temperature controller 112 may each be controlled independently by the controller 114. For example, the temperature controller 112 may be positioned uniformly across the whole area of the stage 111. Through this disposition, the temperature of each area of the wafer w mounted on the stage 111 may be precisely controlled. For example, the controller 114 may control the temperature of each area of the wafer w by heating or cooling the temperature controller 112 vertically overlapping each area of the wafer w. The temperature controller 112 may include a heater for increasing the temperature of the stage 111 and/or a cooler for cooling the temperature of the stage 111. The heater may include a heating wire of which the temperature is increased by electrical resistance or a heat conductor for transmitting heat generated by a separate heat source. The cooler may include a cooling circuit for cooling the temperature of the surroundings through the circulation of a cooling fluid or a Peltier device, that is, an electronic device using the Peltier effect.

Although the temperature controller 112 installed in the stage 111 is described as an example, it should be noted that a temperature controller may also be installed outside the stage 111. For example, a lamp, functioning as a heat source, may be installed outside the stage 111, and may be used as a temperature controller. In this case, the temperature controller installed outside the stage 111 may enable the stage 111 to reach a set temperature. The temperature controller 112 installed in the stage 111 may be controlled such that each area of the stage 111 has a higher or lower temperature than the set temperature and may deform a warpage of the wafer w.

The temperature sensor 113 may sense the temperature of each area of the stage 111. Information sensed by the temperature sensor 113 may be transmitted to the controller 114. The controller 114 may determine whether the temperature of each area of the stage 111 has reached a target temperature, based on the information sensed by the temperature sensor 113. Here, the target temperature refers to a specific temperature value or a specific temperature range. The controller 114 may drive the temperature controller 112 based on the information sensed by the temperature sensor 113.

The warpage sensor 115 may sense the warpage information of the wafer w. Information sensed by the warpage sensor 115 may be transmitted to the controller 114. The controller 114 may set the target temperature of each area of the stage 111, based on the warpage information sensed by the warpage sensor 115. The controller 114 may determine an area, having a shape (e.g., a crying warpage shape) curved upwardly, of the wafer w and an area, having a shape (e.g., a smile warpage shape) curved downwardly, of the wafer w, based on the information sensed by the warpage sensor 115. The controller 114 may apply a higher temperature to the area having a shape curved upwardly than to the area having a shape curved downwardly such that a lower side, closer to the stage 111, of the wafer w expands more than an upper side. The controller 114 may apply a lower temperature to the area having a shape curved downwardly than to the area having a shape curved upwardly such that the lower side, closer to the stage 111, of the wafer w contracts more than the upper side. The warpage sensor 115 may sense the size of a deviation of each area of the wafer w with respect to a reference plane of the wafer w. For example, the warpage sensor 115 may sense the size of the deviation by using a non-contact optical sensor. The size of the deviation for the reference plane may be an average, minimum, or maximum value of the deviation at each point where a warpage is.

The input unit 116 may receive information that is input from a manager of the system 11 for warpage deformation or an external electronic device and may transmit the received information to the controller 114. For example, the input unit 116 may receive the warpage information of the wafer w. The controller 114 may set the target temperature of each area of the stage 111 based on the warpage information received from the input unit 116 and may drive the temperature controller 112. In this case, the system 11 for warpage deformation may operate even without a separate warpage sensor 115.

The output unit 117 may output the warpage information of the wafer w to the manager of the system 11 for warpage deformation or the external electronic device. For example, the output unit 117 may output the warpage information in at least one form of a visual form, an auditory form, or a tactile form. For example, the output unit 117 may output the warpage information through the external electronic device (e.g., a portable terminal of the manager).

An adsorber 119 may adsorb the wafer w to be thermally deformed to the stage 111. For example, the adsorber 119 may be installed in the stage 111. In this case, the stage 111 may be referred to as a wafer chuck. As such, when the adsorber 119 is installed in the stage 111 of the system 11 for warpage deformation, after a warpage of the wafer w has been deformed on the stage 111, the wafer w may be directly fixed by using the adsorber 119, and a semiconductor process may be performed. For example, the semiconductor process may include (i) a thermal oxidation process to form an oxide film; (ii) a lithography process including spin coating, exposure, and development; (iii) a thin film deposition process; and/or (iv) a dry or wet etching process. In other words, according to an embodiment, the warpage deformation process and the semiconductor process may be continuously performed with the same equipment. Thus, the overall semiconductor manufacturing process time may be shortened.

The controller 114 may control the temperature controller 112, the output unit 117, and the adsorber 119, based on information received from the temperature sensor 113, the warpage sensor 115, and the input unit 116. For example, the controller 114 may be a computing device, like a workstation computer, a desktop computer, a laptop computer, or a tablet computer. The controller 114 may be a processor, like a simple controller, a microprocessor, a central processing unit (CPU), or a graphics processing unit (GPU). For example, the controller 114 may be implemented by a general-purpose computer or an application-specific hardware, like a digital signal processor (DSP), a field programmable gate array (FPGA), and an application-specific integrated circuit (ASIC). For example, the operations of the controller 114 may be implemented as instructions stored in a machine-readable medium that may be read and executed by one or more processors. Here, the machine-readable medium may include any mechanism for storing and/or transmitting information in a form that may be read by a machine (e.g., a computing device). For example, the machine-readable medium may include read-only memory (ROM), random-access memory (RAM), magnetic disk storage media, optical storage media, or flash memory devices.

The system 11 for warpage deformation illustrated in FIGS. 1 and 2 are just an example of performing a semiconductor manufacturing method, according to an embodiment. Some of the components described above may be omitted or other components may be added.

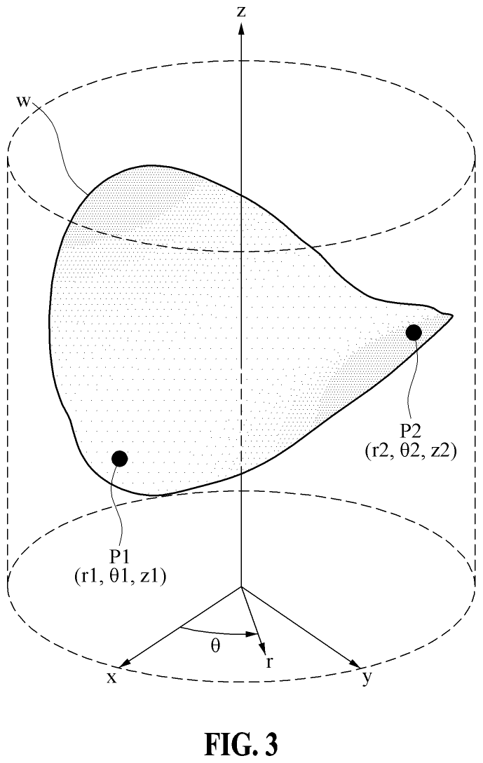

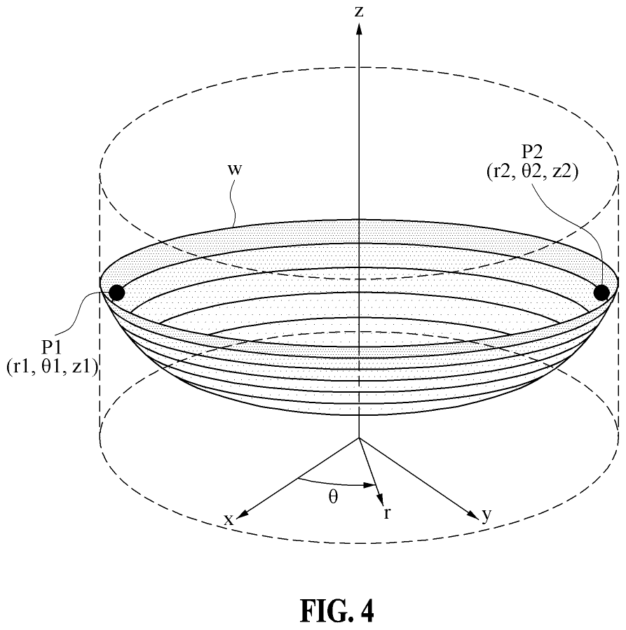

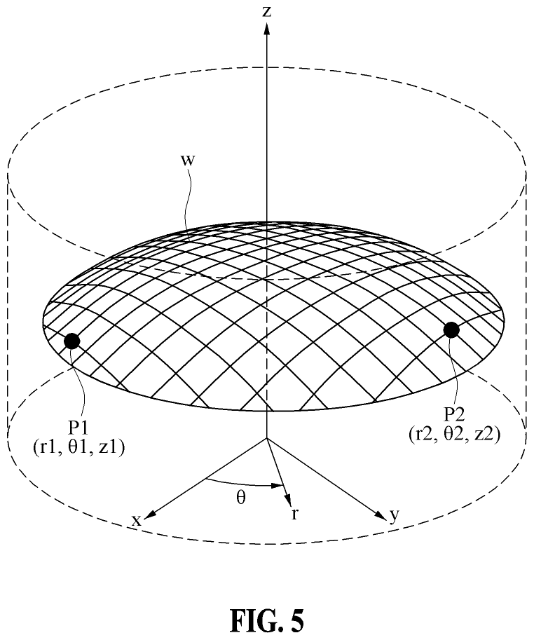

FIG. 3 is a diagram illustrating a three-dimensional warpage in a saddle shape, FIG. 4 is a diagram illustrating a two-dimensional warpage in an arch shape that is convex downwardly, and FIG. 5 is a diagram illustrating a two-dimensional warpage in an arch shape that is convex upwardly.

Referring to FIGS. 3 to 5, examples of the shapes of warpages in the wafer w may be shown. According to an embodiment, a semiconductor process may be performed when a three-dimensional warpage has been deformed into a two-dimensional warpage. Hereinafter, the meaning of the three-dimensional warpage and the two-dimensional warpage is explained.

FIG. 3 illustrates a warpage in a saddle shape, in which a vertical cross-section of a first area, positioned between −45 degrees and +45 degrees with respect to an x-axis, of the wafer w has a smile warpage shape protruding downwardly, and a vertical cross-section of a second area, positioned between −45 degrees and +45 degrees with respect to a y-axis, of the wafer w has a crying warpage shape protruding upwardly. The saddle shape requires a total of three independent variables to fully express a warpage of the wafer w. Here, the three independent variables may include: (i) information (i.e., radius information) about a distance r from a z-axis of a cylindrical coordinate system; (ii) information (i.e., angle information) about an angle θ from an x-axis on a plane (e.g., an x-y plane) perpendicular to the z-axis of the cylindrical coordinate system; and (iii) information (i.e., height information) about a distance z along the z-axis of the cylindrical coordinate system. For example, at points P1 (r1, θ1, z1) and P2 (r2, θ2, z2), even if radii r1 and r2 are the same, if angles θ1 and θ2 are different, heights z1 and z2 of the warpage may be different. As such, the dimension of a warpage may be defined according to the minimum number (e.g., 3) of independent variables required to express the warpage. Since the saddle-shaped warpage requires a total of three pieces of information (the radius information, the angle information, and the height information) to fully express the warpage as described above, the saddle-shaped warpage is a three-dimensional warpage. Meanwhile, it should be noted that the saddle shape illustrated in FIG. 3 is just an example of various shapes of three-dimensional warpages.

FIGS. 4 and 5 respectively illustrate arch-shaped warpages that are convex downwardly and upwardly, which have symmetrical shapes with respect to a specific axis (e.g., a z-axis). Referring to FIG. 4, the vertical cross-section of the whole area of the wafer w has a smile warpage shape protruding downwardly. Referring to FIG. 5, the vertical cross-section of the whole area of the wafer w has a crying warpage shape protruding upwardly. A total of two independent variables are required to fully express the warpages of the wafer w illustrated in FIGS. 4 and 5. Here, the two independent variables include (i) information (i.e., radius information) about the distance r from an axis (e.g., the z-axis) of the cylindrical coordinate system; and (ii) information (i.e., height information) about the distance z along the z-axis of the cylindrical coordinate system. For example, at the points P1 (r1, θ1, z1) and P2 (r2, θ2, z2), when the radii r1 and r2 are the same, regardless of the angles θ1 and θ2, the heights z1 and z2 of the warpage may have the same value. As such, the arch-shaped warpages have symmetrical shapes with respect to a specific axis (e.g., the z-axis). Thus, unlike the saddle shape described above, the warpages of the wafer w may be fully expressed only with two pieces of information (the radius information and the height information) without information about the angle θ. Accordingly, the arch-shaped warpages are two-dimensional warpages. Meanwhile, it should be noted that the arch shape illustrated in FIGS. 4 and 5 is just an example of various shapes of two-dimensional warpages.

According to experiments, generally, the wafer w having a two-dimensional warpage may be chucked by adjusting the adsorption power of a wafer chuck. For example, the wafer w may be fixed to the wafer chuck by increasing the adsorption power of an area of the wafer chuck corresponding to an area, having a large deviation for a reference plane, of the wafer w. On the other hand, in the case of the wafer w having a three-dimensional warpage, due to a symmetrical structure misaligned with a complex surface shape, chucking may be impossible simply by increasing the adsorption power of the wafer chuck, and breaking may occur during chucking. Chucking defects due to wafer warpages have a negative impact directly on the performance and yield of final semiconductor products.

According to an embodiment, by controlling the temperature of each area of the stage 111 (refer to FIG. 1) where the wafer w is mounted and by deforming a three-dimensional warpage into a two-dimensional warpage, the chucking may be performed on the wafer w and the above-described problems may be reduced. In other words, the above-described problems may be reduced by intentionally deforming a warpage into a specific shape of the warpage rather than simply decreasing the warpage.

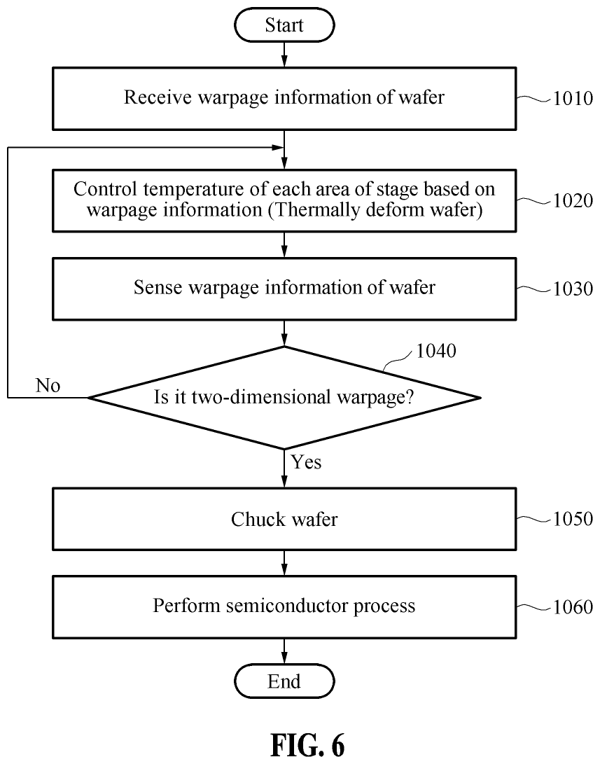

FIG. 6 is a flowchart illustrating a semiconductor manufacturing method using warpage deformation, according to an embodiment.

Hereinafter, the semiconductor manufacturing method using warpage deformation, according to an embodiment, is described with reference to FIGS. 2 and 6. It should be noted that the order of the operations described as an example throughout the present specification, including FIG. 6, is not limited, but the operations may be performed in reverse or simultaneously. In addition, some of the operations may be omitted. For example, the semiconductor manufacturing method, according to an embodiment, may not include operations 1010, 1030, and 1040.

In operation 1010, the warpage information of a wafer may be received. For example, the system 11 for warpage deformation may receive the warpage information of the wafer from the warpage sensor 115 or the input unit 116. The warpage information may include information on a deviation of a warpage by each area of the wafer for a reference plane. For example, the warpage information may include all the information to fully express the warpage, but examples are not limited thereto. The examples of the warpage information are described below.

In operation 1020, a three-dimensional warpage of the wafer may be thermally deformed into a two-dimensional warpage of the wafer by adjusting the temperature of each area of a stage where the wafer is mounted. In operation 1020, one area (e.g., a first area) having any one shape (e.g., a crying warpage shape) between the first area having the crying warpage shape of the wafer and a second area having a smile warpage shape of the wafer may be thermally deformed to have a shape (e.g., the smile warpage shape) of the other area (e.g., the second area). For example, operation 1020 may be performed based on the warpage information received from the warpage sensor 115 or the input unit 116. For another example, operation 1020 may be performed based on the warpage information to be sensed in operation 1030 to be described below. Yet another example, operation 1020 may be performed based on the warpage information received from an external device connected to the system 11 for warpage deformation.

In operation 1030, the warpage information of the wafer may be sensed. Operation 1030 may be performed by the warpage sensor 115 mounted in the system 11 for warpage deformation or may be performed through a measuring facility separate from the system 11 for warpage deformation.

In operation 1040, whether the three-dimensional warpage is thermally deformed into the two-dimensional warpage may be determined. For example, the controller 114 may determine whether the warpage of the wafer has a two-dimensional warpage shape, based on the sensed or received warpage information. For example, when the vertical cross-section of the whole area of the wafer has a smile shape protruding downwardly as illustrated in FIG. 4 or the vertical cross-section of the whole area of the wafer has a crying shape protruding upwardly as illustrated in FIG. 5, the controller 114 may determine that the wafer has a two-dimensional warpage shape. For example, in operation 1040, the output unit 117 may output information to a manager about whether to be thermally transformed into the two-dimensional warpage. Through this, the manager may determine whether additional thermal deformation is required.

If the warpage of the wafer still has a three-dimensional shape in operation 1040, operations 1020 and 1030 may be repeatedly performed. In this case, operation 1020 may include the update of a thermal deformation condition (e.g., a target temperature of each area of the stage and a deformation time of each area of the stage) based on the warpage information newly sensed in operation 1030 and the thermal deformation of the wafer w based on the updated thermal deformation condition.

In operation 1050, the wafer may be chucked into a wafer chuck. For example, operation 1050 may be performed when the wafer has been thermally deformed into a two-dimensional warpage shape. In operation 1050, the adsorption power of the adsorber 119 may increase in an area having a greater deviation for the reference plane of the wafer. Through this method, the wafer having a two-dimensional warpage shape may be fixed to the wafer chuck.

Meanwhile, a deviation of the warpage of the wafer for the reference plane is less than a set value, operation 1050 may be performed like the wafer being thermally deformed into a two-dimensional warpage shape. In other words, operation 1050 may be performed when the deviation of the warpage of the wafer for the reference plane is less than the set value regardless of the result of operation 1040 or without operation 1040 being performed.

In operation 1060, a semiconductor process may be performed while the wafer is chucked. For example, the semiconductor process may include: (i) a thermal oxidation process to form an oxide film; (ii) a lithography process including spin coating, exposure, and development; (iii) a thin film deposition process; and/or (iv) a dry or wet etching process. This semiconductor process is a process that requires the temperature of the wafer should be maintained at a set temperature, and a temperature controller may be mounted on the wafer chuck. In other words, a temperature controller mounted on a wafer chuck of a semiconductor process facility may be used as the temperature controller 112 of the system 11 for warpage deformation. In other words, the stage of the system 11 for warpage deformation and the adsorber 119 of the system 11 for warpage deformation may be used as the wafer chuck of the semiconductor process facility such that the warpage deformation process and the semiconductor process may be continuously performed.

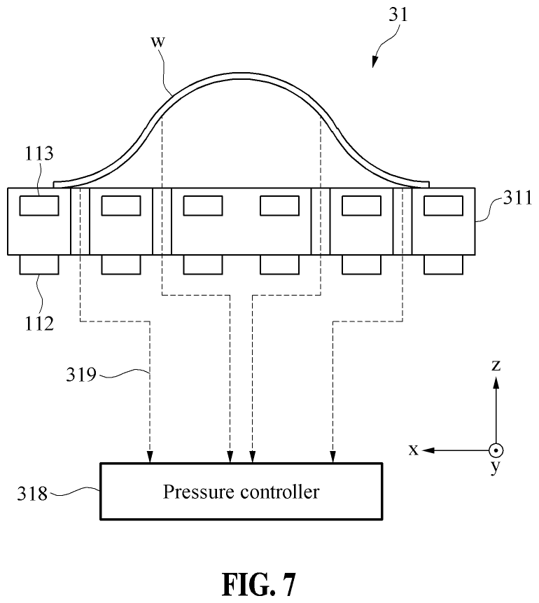

FIG. 7 is a side view of a system for warpage deformation, according to an embodiment.

Referring to FIG. 7, a system 31 for warpage deformation, according to an embodiment, may include a stage 311, the temperature controller 112, the temperature sensor 113, a pressure controller 318, and an adsorption line 319.

The temperature controller 112 is installed in the stage 311 and may control a calorie transmitted to the wafer w through the stage 311. FIG. 7 illustrates an example of the temperature controller 112 being installed on the bottom surface of the stage 311, but the installation position is not limited thereto. For example, the temperature controller 112 may be installed on the top surface of the stage 311 and may be embedded inside the stage 311.

The temperature sensor 113 is installed in the stage 311 and may sense the temperature of each area of the stage 311 heated or cooled through the temperature controller 112. FIG. 7 illustrates an example of the temperature sensor 113 being installed inside the stage 311, but the installation position is not limited thereto. For example, the temperature sensor 113 may be installed on the top surface of the stage 311 and may be installed on the bottom surface of the stage 311.

The pressure controller 318 and the adsorption line 319 may be examples of adsorber (e.g., the adsorber 119 of FIG. 2) controlled by a controller (e.g., the controller 114 of FIG. 2). In this configuration, the wafer w may be adsorbed through a vacuum method. In other words, the stage 311 of the system 31 for warpage deformation may be understood as a vacuum chuck. The vacuum level of each adsorption line 319 may be controlled by the pressure controller 318, and the adsorption power of each area of the stage 311 may be controlled.

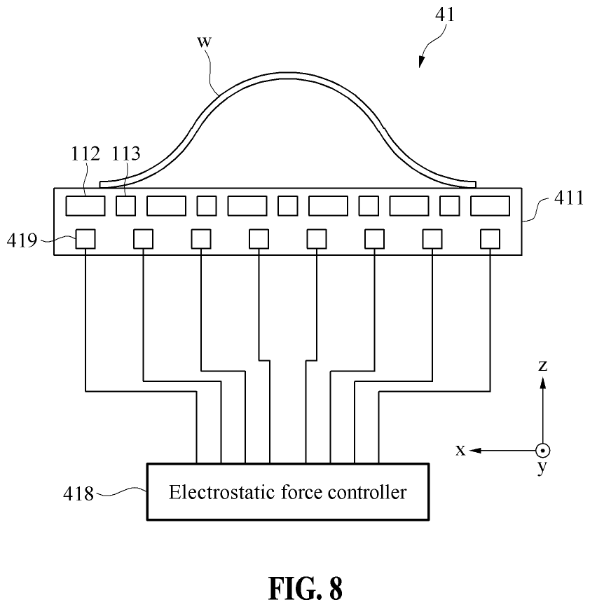

FIG. 8 is a side view of a system for warpage deformation, according to an embodiment.

Referring to FIG. 8, a system 41 for warpage deformation, according to an embodiment, may include a stage 411, the temperature controller 112, the temperature sensor 113, an electrostatic force controller 418, and an adsorption electrode 419.

The stage 411 may include a dielectric layer. The dielectric layer may include, for example, a dielectric, like an aluminum oxide (Al2O3) layer, an aluminum nitride (AlN) layer, an yttrium oxide (Y2O3) layer, or resin, e.g., polyimide.

The electrostatic force controller 418 and the adsorption electrode 419 may be examples of adsorber (e.g., the adsorber 119 of FIG. 2) controlled by a controller (e.g., the controller 114 of FIG. 2). In this configuration, the wafer w may be adsorbed through an electrostatic force method. In other words, the stage 411 of the system 41 for warpage deformation may be understood as an electrostatic chuck. Charges may be accumulated in each of the adsorption electrode 419 by the electrostatic force controller 418, and the accumulated charges may induce charges on a wafer surface. The induced charges may generate electrostatic force such that the wafer w may be adsorbed to the stage 411. The size of voltage of the adsorption electrode 419 may be controlled by the electrostatic force controller 418 and the electrostatic force of each area of the stage 411 may be controlled.

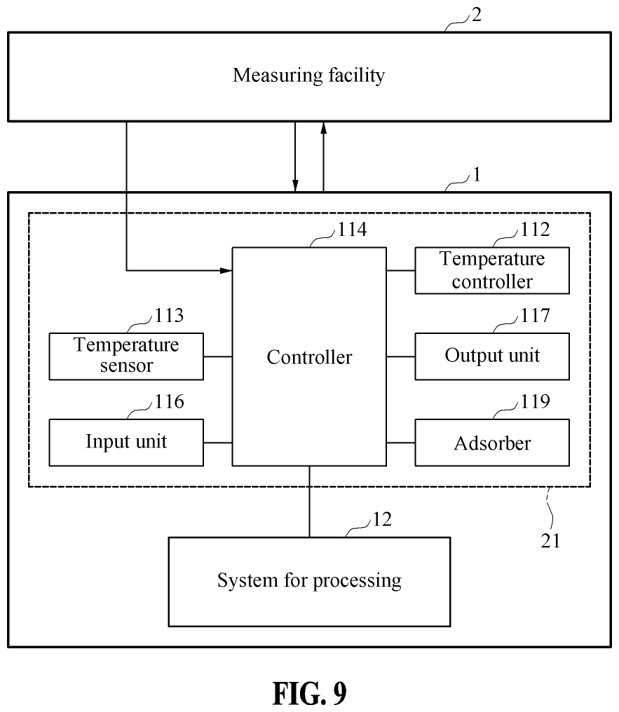

FIG. 9 is a block diagram illustrating a semiconductor process facility, including a system for warpage deformation, and a measuring facility, according to an embodiment.

Referring to FIG. 9, the semiconductor process facility, according to an embodiment, may include a semiconductor process facility 1 and a measuring facility 2.

The semiconductor process facility 1 may include a system 21 for warpage deformation and a system 12 for processing. The system 21 for warpage deformation may include the temperature controller 112, the temperature sensor 113, the controller 114, the input unit 116, the output unit 117, and the adsorber 119.

The system 12 for processing may perform a semiconductor process while adsorbing a thermally deformed wafer by using the system 21 for warpage transformation. In other words, by using the adsorber 119 installed in a stage of the system 21 for warpage deformation, the warpage deformation process of the wafer and the semiconductor process may be continuously performed. Through this method, a semiconductor process time may be shortened compared to when using separate equipment for warpage deformation.

The measuring facility 2 is a facility for measuring a warpage of the wafer and may transmit and receive the wafer to and from the semiconductor process facility 1. The measuring facility 2 may transmit and receive the wafer to and from a semiconductor process facility for performing other processes, besides the above-described semiconductor process facility 1. Since a warpage sensor is not required to be installed in each of semiconductor process facilities in this method, installation costs of the warpage sensor may be saved. The controller 114 may control the temperature controller 112 by using warpage information received from the measuring facility 2.

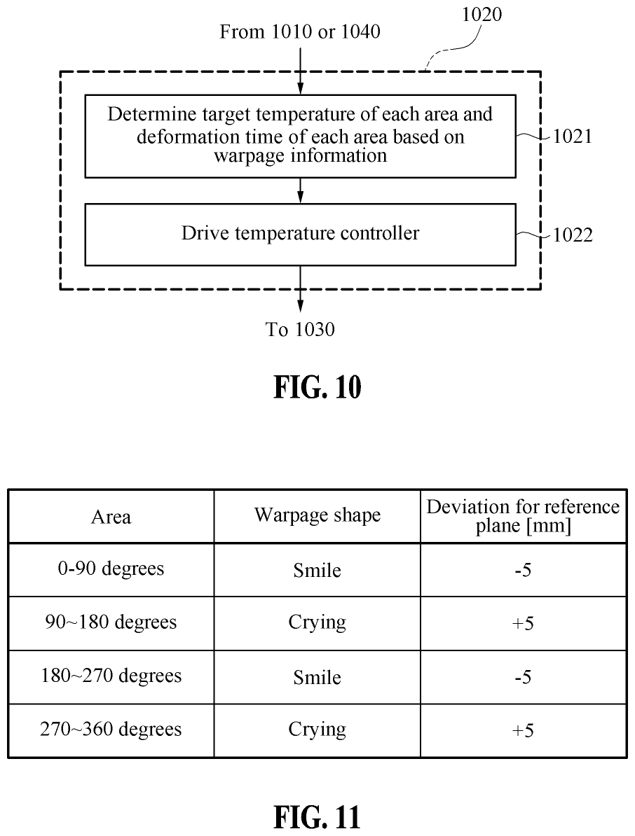

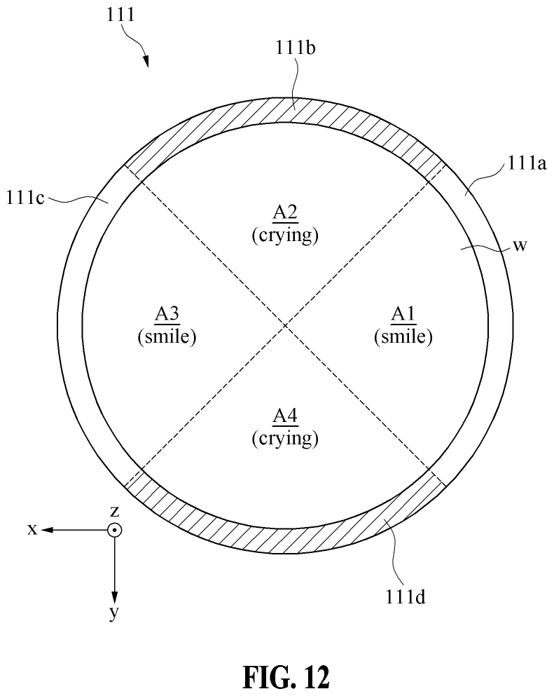

FIG. 10 is a flowchart illustrating a method of adjusting a temperature of each area of a stage, according to an embodiment, FIG. 11 is a table showing warpage information according to an embodiment, and FIG. 12 is a top view of a wafer and a stage, showing a method of adjusting a temperature of each area of the stage, according to an embodiment.

Referring to FIGS. 6 and 10 to 12, according to an embodiment, in operation 1020 of thermally deforming the wafer w, a target temperature of each area of the stage 111 and a deformation time of each area of the stage 111 may be determined based on the warpage information (operation 1021). For example, the warpage information may be the warpage information received in operation 1010 and may include the warpage information sensed in operation 1030. For example, the warpage information may include a warpage shape of each area of the wafer w and a deviation of each area of the wafer w for a reference plane. For example, if the wafer w has a saddle-shaped warpage, the warpage information may be given as illustrated in FIG. 11. FIG. 11 illustrates an example of a smile-shaped warpage and a crying-shaped warpage alternately appearing at the same angle, but a range of an area where each warpage shape appears may vary. It should be noted that the deviation of a warpage for the reference plane may also vary depending on areas.

In operation 1021, the target temperature of each area of the stage 111 may be set based on warpage shape information. For example, when the warpage information is given as illustrated in FIG. 11, an area, vertically overlapping at least one area of a first area (e.g., an area A2 or A4) and a second area (e.g., an area A1 or A3), of the stage 111 may be heated or cooled such that the temperature of the first area (e.g., the area A2 or A4), having a crying warpage shape, of the wafer w is higher than the temperature of the second area (e.g., the area A1 or A3), having a smile warpage shape, of the wafer w as illustrated in FIG. 12. For example, the first area (e.g., the area A2 or A4) may be heated at a higher temperature than that of the second area (e.g., the area A1 or A3). For example, only the first area (e.g., the area A2 or A4) may be heated. For another example, the second area (e.g., the area A1 or A3) may be cooled at a lower temperature than that of the first area (e.g., the area A2 or A4). For example, only the second area (e.g., the area A1 or A3) may be cooled. Hereinafter, for ease of description, the example of only heating the first area (e.g., the area A2 or A4) is provided, but those skilled in the art may fully understand that other methods are also possible.

In operation 1021, the deformation time of each area of the stage 111 may be set to be longer as the deviation for the reference plane is greater. For example, when an absolute value of the deviation of each area for the reference plane is the same as illustrated in FIG. 11, the deformation time of each area may be set to be the same.

The target temperature and deformation time of each area of the stage 111 may be determined by using, for example, a commercial simulation program. When using a program that simulates a warpage according to a temperature gradient and a physical property value of an object, like the wafer w, information on a calorie that may deform a three-dimensional warpage into a two-dimensional warpage may be calculated. Based on this calorie information, the target temperature and deformation time of each area of the stage 111 may be determined. For example, the target temperature and deformation time of each area of the stage 111 may be determined through experiments. By performing experiments using the actual wafer w having a three-dimensional warpage, the target temperature and deformation time of each area of the stage 111 to deform the three-dimensional warpage into a two-dimensional warpage may be acquired. Based on the acquired information, the target temperature and deformation time of each area of the stage 111 may be determined according to the warpage information. Said two methods may be performed independently, but it should be noted that the methods may be performed by being combined as the commercial simulation program is first used, and then, experiments may be performed for fine-tuning.

In operation 1022, at least one temperature controller installed in the stage 111 may be driven based on the determined target temperature of each area and the determined deformation time of each area. For example, when the warpage information is given as illustrated in FIG. 11, the stage 111 may be divided into four areas 111a, 111b, 111c, and 111d according to each area of the wafer w as illustrated in FIG. 12. For example, the temperature controller positioned in two areas 111b and 111d vertically overlapping the first area (e.g., the area A2 or A4) having a crying-shaped warpage among the divided four areas may be heated. In this case, with the crying-shaped warpage deformed into a smile-shaped warpage, the wafer w may have a two-dimensional warpage shape.

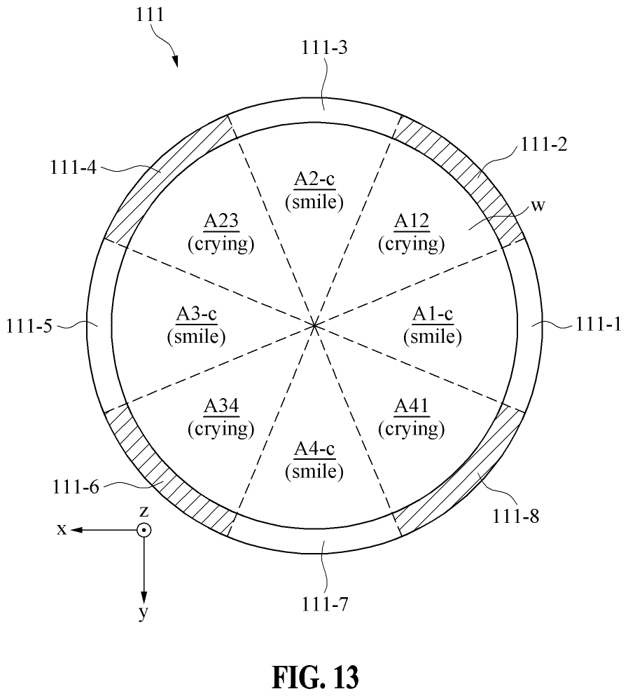

FIG. 13 is a top view of a wafer and a stage, showing a method of adjusting a temperature of each area of the stage, according to an embodiment.

Referring to FIGS. 12 and 13, a three-dimensional warpage having more complex shape than that of the saddle-shaped warpage illustrated in FIG. 12 is shown. As described below, the wafer w of FIG. 12 is divided into a first area A1 to a fourth area A4 based on the boundaries of warpage shapes.

When heating the second area A2 having a crying shape and the fourth area A4 having a crying shape of the wafer w having a saddle-shaped warpage, like in FIG. 12, their central portions A2-c and A4-c may be deformed into a smile shape as illustrated in FIG. 13. Meanwhile, a central portion A1-c of the first area A1 and a central portion A3-c of the third area A3, which are not heated or cooled, maintain their smile shapes as they are. Central areas A12, A23, A34, and A41 of FIG. 13, which are positioned near the boundaries of the first area A1 to the fourth area A4 illustrated in FIG. 12, may be deformed into a crying shape due to the deformation of adjacent areas. As such, when the wafer w has a new three-dimensional warpage shape after thermal deformation, additional thermal deformation may be performed by changing thermal deformation conditions.

In other words, operation 1020 of thermal deformation may include a first thermal deformation operation and a second thermal deformation operation having different thermal deformation conditions.

For example, in the first thermal deformation operation, two areas (e.g., areas 111b and 111d) spaced apart from each other in an angular direction among four areas 111a to 111d into which the stage 111 is divided according to angles as illustrated in FIG. 12 may be heated or cooled at a temperature different from that of the other two areas (e.g., the areas 111a and 111c).

For example, in the second thermal deformation operation, four areas (e.g., areas 111-2, 111-4, 111-6, and 111-8) spaced apart from one another in an angular direction among eight areas 111-1 to 111-8 into which the stage 111 is divided according to angles as illustrated in FIG. 13 may be heated or cooled at a temperature different from that of the other four areas (e.g., the areas 111-1, 111-3, 111-5, and 111-7).

As such, it should be noted that, when a change of a warpage shape is expected in a thermal deformation process, a plurality of different thermal deformation operations having different thermal deformation conditions may be sequentially performed.

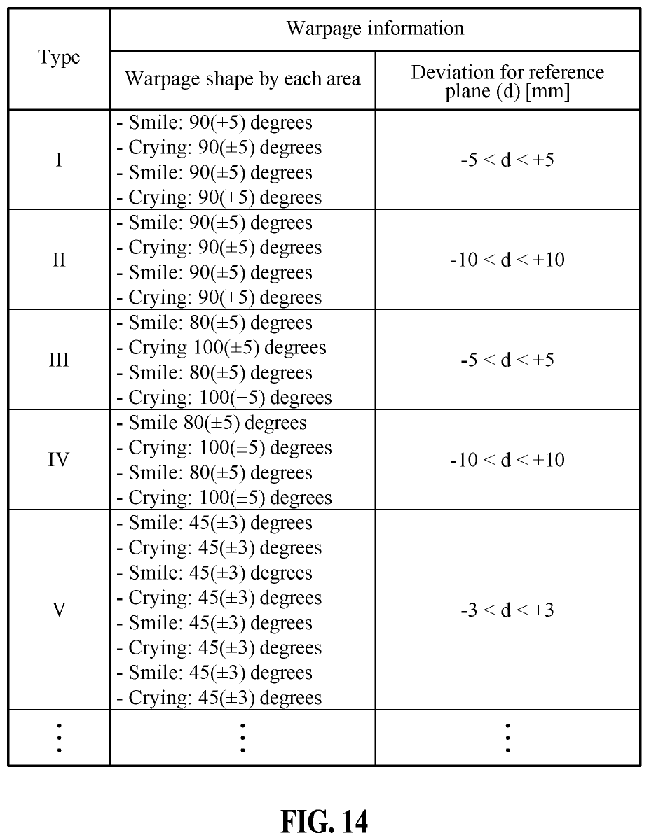

FIG. 14 is a table showing warpage types according to an embodiment.

Referring to FIGS. 10 and 14, warpage types classified according to warpage information are shown. Since a warpage, generated by each semiconductor process, of a wafer may have a certain tendency, the warpage types may be classified according to the warpage information and a thermal deformation condition may be set based on which warpage type the warpage belongs to. In other words, in operation 1021 of FIG. 10, the target temperature of each area of the stage and the deformation time of each area of the stage may be determined according to which warpage type a warpage of the wafer belongs to among the warpage types.

For example, the warpage type may include the shape information of each warpage area of the wafer and deviation information for a reference plane as illustrated in FIG. 14. For example, the shape information of each warpage area of the wafer may include the angle information of each shape, which allows a setting error (e.g., ±5 degrees or ±3 degrees). For example, the deviation information for the reference plane may be set as a value in a set range.

For example, (i) the warpage of the wafer may include a 95-degree smile shape, an 85-degree crying shape, a 95-degree smile shape, and an 85-degree crying shape; and (ii) if the deviation of the warpage of the wafer for the reference plane is 3 mm, the warpage of the wafer may be determined to belong to type I. In this case, ignoring the setting error (±5 degrees) of type I, a heated area of the stage or a cooled area of the stage may be determined based on a thermal deformation condition for the warpage of the wafer including a 90-degree smile shape, a 90-degree crying shape, a 90-degree smile shape, and a 90-degree crying shape. The target temperature and deformation time of a temperature controller may be set based on, for example, the maximum deviation (5 mm) of type I.

Through this method, by using a thermal deformation condition for each type, the number of simulations and/or experiments to determine thermal deformation conditions may be reduced, and thus, the efficiency of the overall semiconductor manufacturing process may be improved.

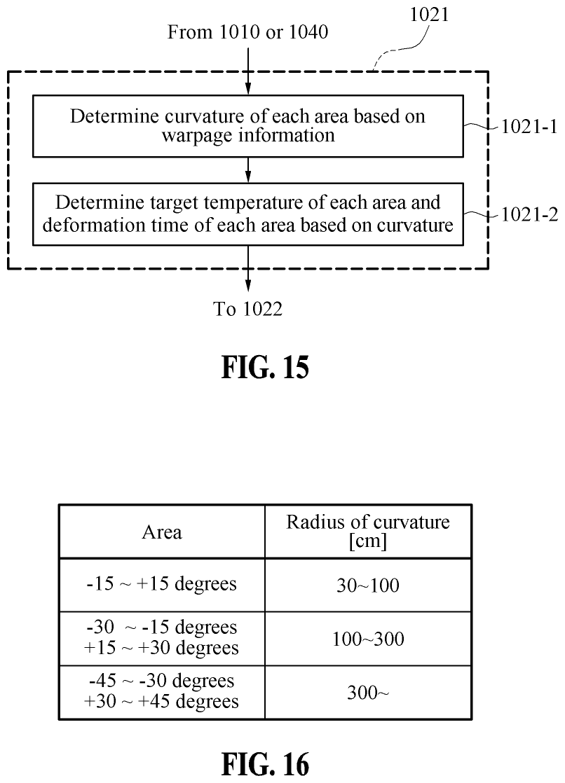

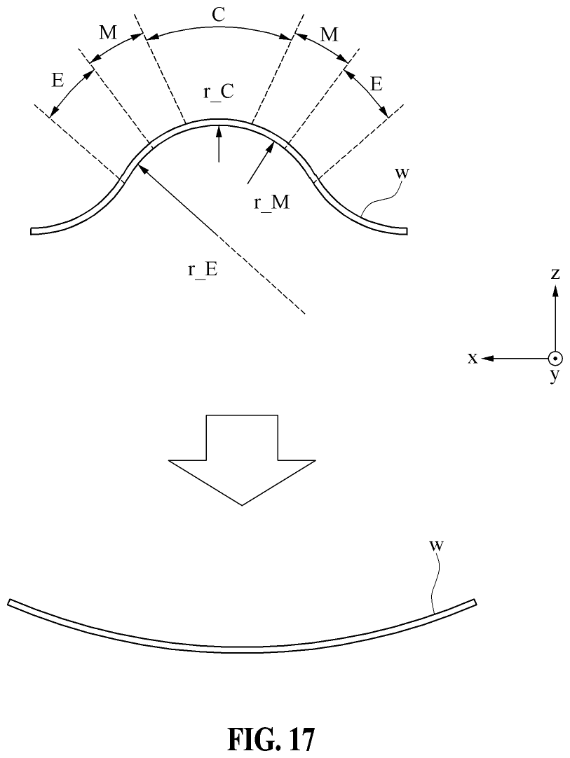

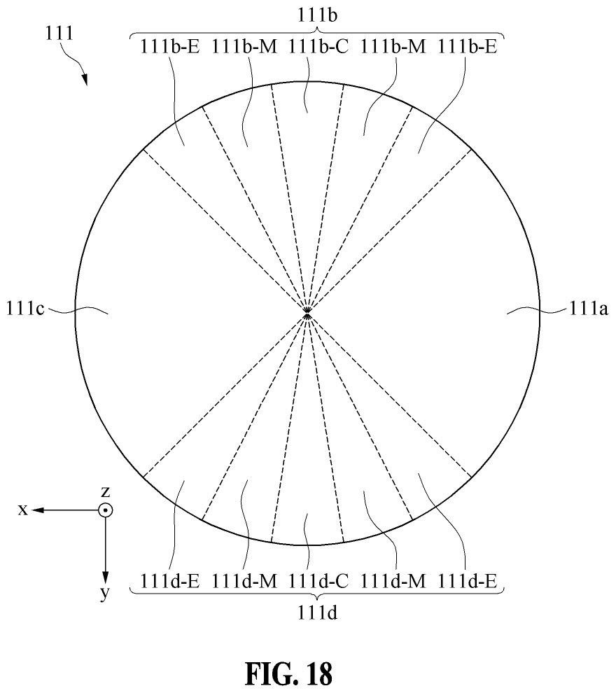

FIG. 15 is a flowchart illustrating a method of determining a target temperature of each area of the stage and a deformation time of each area of the stage, according to an embodiment, FIG. 16 is a table representing the warpage information according to an embodiment, FIG. 17 is a side view of deformation of a three-dimensional warpage into a two-dimensional warpage through a semiconductor manufacturing method using warpage deformation, according to an embodiment, and FIG. 18 is a top view of divided areas of a stage, according to an embodiment.

Referring to FIGS. 6, 10, and 15 to 18, in operation 1021 of determining the target temperature of each area and the deformation time of each area, according to an embodiment, a curvature of each area of a wafer may be determined based on the warpage information (operation 1021-1). For example, the warpage information may be the warpage information received in operation 1010 and may include the warpage information sensed in operation 1030. For example, the warpage information may include information on a radius of curvature of the warpage of each area of the wafer w. Here, the radius of curvature may be a radius of an imaginary circle when the imaginary circle, which is bent at a position at the same degree as that of a curved line passing through the position on a curved surface or a curved line, is drawn. The curvature is expressed by a reciprocal number of the radius of curvature. Thus, as the curvature is greater (e.g., the bending is greater), the radius of curvature may have a smaller value.

For example, if the wafer w has a saddle-shaped warpage, the warpage information may be given as illustrated in FIG. 16. In other words, in an area having any one shape (e.g., a crying shape) between the crying shape and a smile shape of the wafer w as illustrated in FIG. 17, a central portion C positioned in the center of the area may have the smallest radius r_C of curvature, an edge portion E positioned at the edge of the area may have the largest radius r_E of curvature, and a radius r_M of curvature of a middle portion M positioned in the middle of the area may have a value therebetween.

In operation 1021-2, based on the determined curvature, the target temperature of each area and the deformation time of each area may be determined. Through operation 1021-2, by differing the degree of heating or cooling in each area, the warpage having different curvatures in each area may be deformed into a desired shape.

For example, a first area (e.g., a crying-shaped area) corresponding to a heating or cooling target may include a first sub-area (e.g., the central portion C) having a first radius (e.g., the radius r_C of curvature) of curvature, a second sub-area (e.g., the edge portion E) having a second radius (e.g., the radius r_E of curvature) of curvature greater than the first radius (e.g., the radius r_C of curvature) of curvature, and a third sub-area (e.g., the middle portion M) having a third radius (e.g., the radius r_M of curvature) of curvature that is greater than the first radius (e.g., the radius r_C of curvature) of curvature and less than the second radius (e.g., the radius r_E of curvature) of curvature. In this case, an area, vertically overlapping at least one sub-area between the first sub-area (e.g., the central portion C) and the second sub-area (e.g., the edge portion E), of the stage may be heated or cooled such that a calorie change per unit volume in the first sub-area (e.g., the central portion C) may be greater than a calorie change per unit volume in the second sub-area (e.g., the edge portion E). Meanwhile, a calorie change per unit volume in the third sub-area (e.g., the middle portion M) may be determined as a value between the calorie changes per unit volume of the other sub-areas (e.g., the central portion C and the edge portion E). As such, by setting a calorie change per unit volume to be greater for an area that has a greater curvature in a thermal deformation process, deformation may be performed such that curvatures of areas may be uniform.

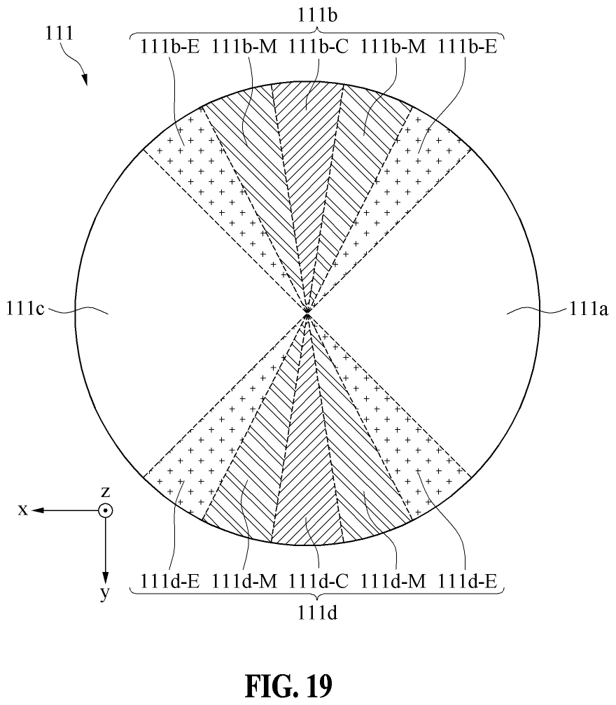

In operation 1021-2, for the control of calorie changes by curvatures as described above, as illustrated in FIG. 18, the stage 111 may be divided into four areas (e.g., the areas 111a to 111d) depending on the warpage shapes of the wafer, a first area (e.g., the area 111b or 111d) having the same warpage shape (e.g., the crying warpage shape) among them may be divided into a central portion (e.g., a central portion 111b-C or 111d-C), an edge portion (e.g., an edge portion 111b-E or 111d-E), and a middle portion (e.g., a middle portion 111b-M or 111d-M). As such, by differently setting the target temperature and/or the deformation time for each divided area, the calorie changes of each sub-area (e.g., the central portion C, the middle portion M, and the edge portion E) of the wafer may be different. The exemplary method of operation 1021-2 is described below with reference to FIGS. 19 to 21.

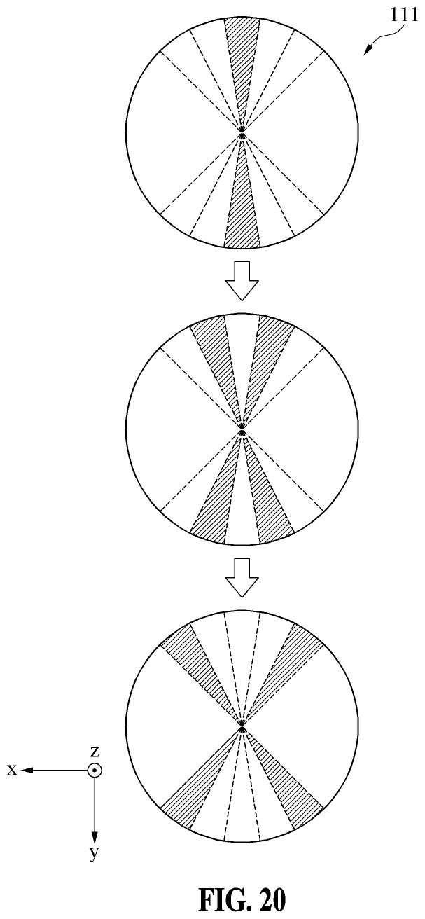

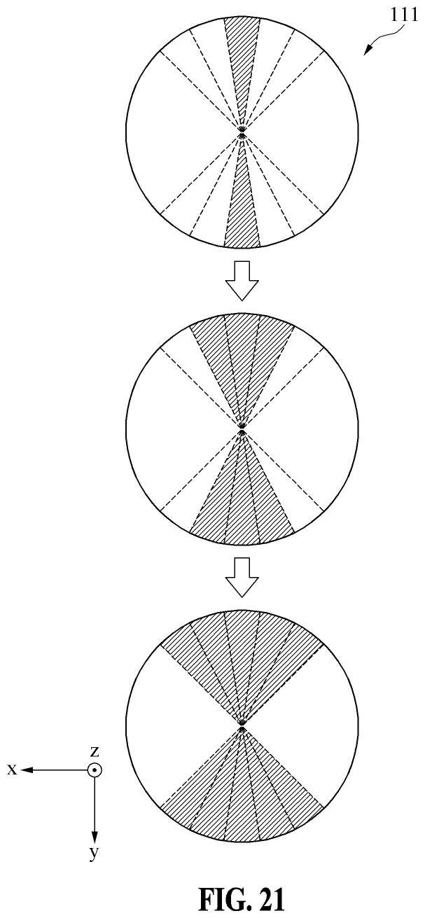

FIG. 19 is a diagram illustrating a method of varying target temperatures depending on areas of a stage, according to an embodiment, and FIGS. 20 and 21 are diagrams each illustrating a method of varying deformation times depending on areas of the stage, according to an embodiment. The reference numerals of FIG. 19 may also apply to those of FIGS. 20 and 21.

Referring to FIG. 19, the stage 111 may be divided into four areas 111a, 111b, 111c, and 111d according to each area of the wafer w. Among the divided four areas 111a, 111b, 111c, and 111d, a first area (e.g., the area 111b or 111d) corresponding to the area of the wafer w having a crying-shaped warpage may be determined as a heating target. The first area (e.g., the area 111b or 111d) may be subdivided into a plurality of areas according to angular directions. For example, the first area (e.g., the area 111b or 111d) may be divided into the central portion 111b-C or 111d-C, the edge portion 111b-E or 111d-E, and the middle portion 111b-M or 111d-M. The temperature of a temperature controller positioned in the middle portion 111b-M or 111d-M may be set to be higher than the temperature of a temperature controller positioned in the edge portion 111b-E or 111d-E. In this configuration, a calorie provided to a wafer positioned at an upper side of the central portion 111b-C or 111d-C may be higher than a calorie provided to a wafer positioned at an upper side of the edge portion 111b-E or 111d-E during the same time. Likewise, the temperature of the temperature controller positioned in the middle portion 111b-M or 111d-M may be set to be lower than the temperature of a temperature controller positioned in the central portion 111b-C or 111d-C and higher than the temperature of the temperature controller positioned in the edge portion 111b-E or 111d-E. Accordingly, like a saddle-shaped warpage, when a curvature of the wafer is different in each area, a warpage of each area of the wafer may be effectively deformed. Meanwhile, although thermal deformation by heating is described above as an example, a similar method may also apply to thermal deformation by cooling.

Referring to FIG. 20, the temperature controller respectively positioned in the central portion 111b-C or 111d-C, the edge portion 111b-E or 111d-E, and the middle portion 111b-M or 111d-M may be independently controlled. Through this method, the temperature controller may be appropriately controlled such that a warpage may be deformed depending on a curvature of the wafer corresponding to each area. For example, the temperature controller positioned in the central portion 111b-C or 111d-C may be driven for a longer time than the temperature controller positioned in the edge portion 111b-E or 111d-E.

Referring to FIG. 21, a first time for which the temperature controller positioned in the central portion 111b-C or 111d-C is driven may be set to be longer than a second time for which the temperature controller positioned in the edge portion 111b-E or 111d-E is driven. In addition, at least some of the first time may overlap with the second time. Through this method, the warpage of a plurality of areas may be simultaneously deformed while a portion having the largest curvature of the warpage has been deformed to a similar degree to a curvature of the remaining portion, and thus, the warpage may be deformed at a faster pace compared to that of FIG. 20.

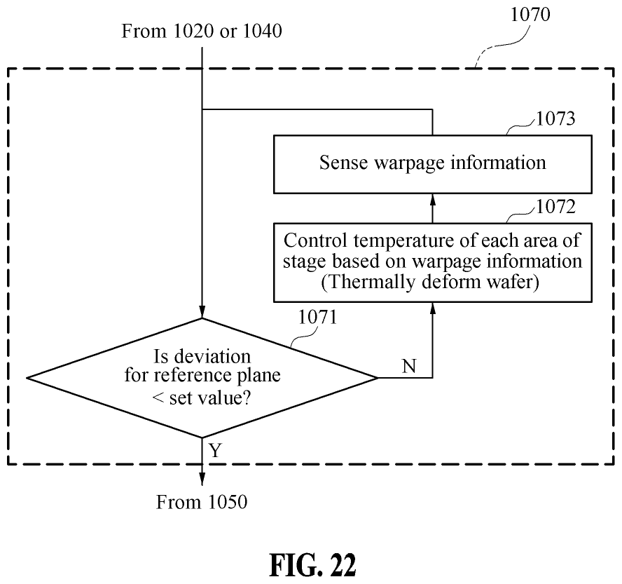

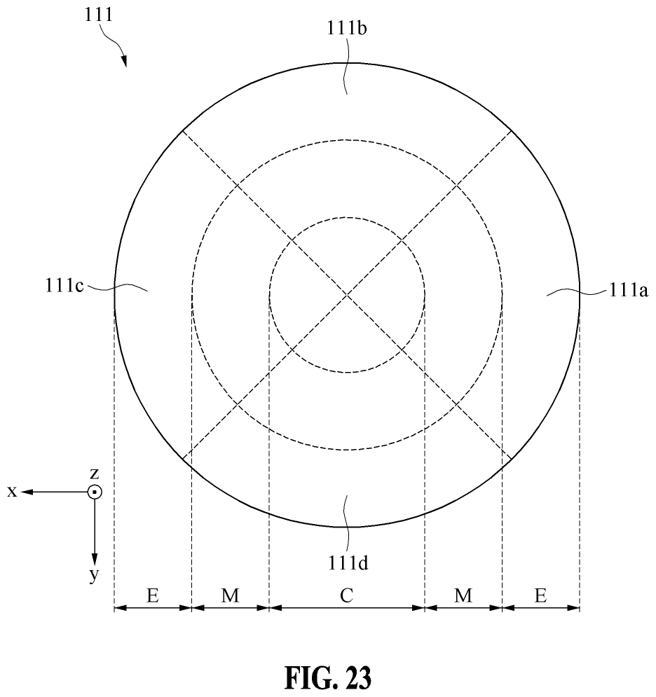

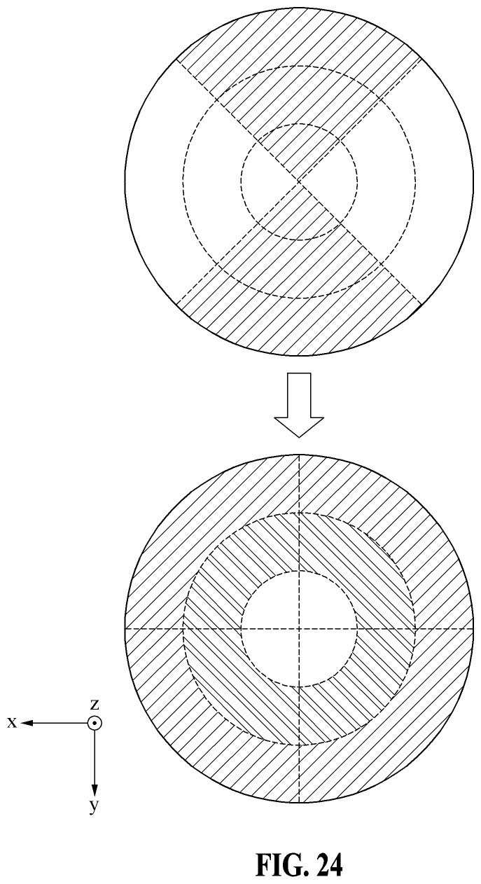

FIG. 22 is a flowchart illustrating a semiconductor manufacturing method using warpage deformation, according to an embodiment, FIG. 23 is a top view of a stage, showing divided areas, according to an embodiment, and FIG. 24 is a diagram illustrating a method of varying deformation times depending on areas of the stage, according to an embodiment.

Referring to FIGS. 6 and 22 to 24, according to an embodiment, a semiconductor manufacturing method using warpage deformation may include operation 1070 of decreasing a deviation of a warpage for a reference plane by heating or cooling the stage by each area, based on warpage information.

For example, operation 1070 may be performed when a wafer has been determined to have a two-dimensional warpage shape in operation 1040. In other words, after the warpage of the wafer is deformed into the two-dimensional shape, additional thermal deformation may be performed to decrease the deviation of the warpage of the two-dimensional shape for the reference plane.

Operation 1070 may include operation 1071 of determining whether the deviation of the warpage for the reference plane is less than a set value, operation 1072 of controlling the temperature of each area of the stage based on the warpage information, and operation 1073 of sensing the warpage information.

Operation 1072 may be performed when the deviation of the warpage for the reference plane is greater than or equal to the set value in operation 1071. For example, operation 1072 may be performed by heating or cooling at least one area of a plurality of areas, e.g., the central portion C, the middle portion M, and the edge portion E, into which the stage 111 is divided in a radial direction as illustrated in FIG. 23. FIG. 23 illustrates the stage 111 being divided into four areas 111a, 111b, 111c, and 111d in an angular direction according to the saddle-shaped warpage. According to an embodiment, the four areas 111a, 111b, 111c, and 111d of the stage 111 may each be subdivided in a radial direction as illustrated in the drawings into the central portion C positioned in the center of the stage 111, the edge portion E positioned in the edge of the stage 111, and the middle portion M positioned between the central portion C and the edge portion E. When driving the temperature controller in each area subdivided as such, by using the same stage 111, (i) the temperature may be independently controlled in each area divided in an angular direction; and/or (ii) the temperature may be independently controlled in each area divided in a radial direction. In other words, as illustrated in FIG. 24, (i) a thermal deformation operation of deforming a three-dimensional warpage into a two-dimensional warpage; and (ii) a thermal deformation operation of decreasing the deviation of the two-dimensional warpage for the reference plane may be continuously performed without replacing the stage 111. In addition, when controlling the target temperature or the deformation time in each area divided in a radial direction, the deviation of the two-dimensional shape having different curvatures in a radial direction may be efficiently reduced.

For another example, operation 1070 may be performed after operation 1020 of thermally deforming the wafer. In other words, even before the warpage of the three-dimensional shape is deformed into the warpage of the two-dimensional shape, when the deviation for the reference plane is sufficiently small to perform chucking, operation 1050 of chucking the wafer may be performed. In other words, the wafer may be deformed through two-step thermal deformation. For example, in a first thermal deformation step, among the four areas 111a, 111b, 111c, and 111d into which the stage 111 is divided according to angles, two areas 111b and 111d spaced apart from each other in an angular direction may be heated or cooled at a temperature different from that of the other two areas. In a second thermal deformation step, the deviation of the two-dimensional warpage of the wafer for the reference plane may be reduced with at least one area of the plurality of areas, e.g., the central portion C, the middle portion M, and the edge portion E, into which the stage 111 is divided in a radial direction being heated or cooled.

A number of embodiments have been described above. Nevertheless, it should be understood that various modifications may be made to these embodiments. For example, suitable results may be achieved if the described techniques are performed in a different order, and/or if components in a described system, architecture, device, or circuit are combined in a different manner, or replaced or supplemented by other components or their equivalents.

Therefore, other implementations, other example embodiments, and/or equivalents of the claims are within the scope of the following claims.

What is claimed is:

1. A semiconductor manufacturing method using warpage deformation, the semiconductor manufacturing method comprising:
thermally deforming a three-dimensional warpage of a wafer into a two-dimensional warpage of the wafer by adjusting a temperature of each area of a plurality of areas of a stage where the wafer is mounted;
chucking the wafer when the three-dimensional warpage of the wafer has been deformed into the two-dimensional warpage of the wafer; and
performing a semiconductor process while the wafer is chucked.

2. The semiconductor manufacturing method of claim 1, wherein, in the thermally deforming, the stage is heated or cooled such that a temperature of a first area of the plurality of areas of the stage, overlapping a portion of the wafer having a crying warpage shape is higher than a temperature of a second area of the plurality of areas of the stage overlapping another portion of the wafer having a smile warpage shape.

3. The semiconductor manufacturing method of claim 2, further comprising receiving warpage information of the wafer, and
the thermally deforming comprises:
determining a target temperature of each area of the plurality of areas of the stage and a deformation time of each area of the plurality of areas, based on the warpage information; and
driving at least one temperature controller installed in the stage, based on the determined target temperature of each area of the plurality of areas and the determined deformation time of each area of the plurality of areas.

4. The semiconductor manufacturing method of claim 3, wherein the warpage information comprises warpage shape information of each area of a plurality of areas of the wafer overlapping corresponding areas of the plurality of areas of the stage and deviation information for a reference plane of each area of the plurality of areas of the wafer,
the target temperature of each area of the plurality of areas of the stage is set based on the warpage shape information of each area of the plurality of areas of the wafer, and
the deformation time of each area overlapping corresponding areas of the plurality of areas of the stage is set to be longer as a deviation for the reference plane is greater.

5. The semiconductor manufacturing method of claim 3, wherein the warpage information comprises warpage shape information of each area of the plurality of areas of the wafer and deviation information for a reference plane of each area of the plurality of areas of the wafer, and,
the target temperature of each area of the plurality of areas of the stage and the deformation time of each area of the stage are determined based on which warpage type a warpage of the wafer belongs to among warpage types classified according to the warpage information.

6. The semiconductor manufacturing method of claim 2, further comprising:
measuring warpage information of the wafer;
determining whether the warpage shape of the wafer is a two-dimensional warpage shape, based on the warpage information; and
outputting whether the warpage shape of the wafer is a two-dimensional warpage shape to a manager.

7. The semiconductor manufacturing method of claim 2, further comprising:
measuring warpage information of the wafer; and
determining whether the warpage shape of the wafer is a two-dimensional warpage shape, based on the warpage information, and
if the warpage shape of the wafer is not a two-dimensional warpage shape, the thermally deforming is performed again based on the measured warpage information.

8. The semiconductor manufacturing method of claim 7, further comprising determining whether a deviation of a warpage of the wafer for a reference plane is less than a set value, and
the chucking the wafer is performed when the deviation of the warpage for the reference plane is less than the set value.

9. The semiconductor manufacturing method of claim 8, further comprising decreasing a deviation of a two-dimensional warpage of the wafer for the reference plane by heating or cooling the stage by each area of the plurality of areas of the stage, based on the warpage information of the wafer.

10. The semiconductor manufacturing method of claim 2, wherein, in the thermally deforming, an area of the plurality of areas of the stage, vertically overlapping at least one sub-area of a first sub-area and a second sub-area, of the stage is heated or cooled such that a calorie change per unit volume in the first sub-area, having a first radius of curvature, of the first area is greater than a calorie change per unit volume in the second sub-area, having a second radius of curvature greater than the first radius of curvature, of the first area.

11. The semiconductor manufacturing method of claim 10, wherein, in the thermally deforming, a temperature in the first sub-area and a temperature in the second sub-area are set differently.

12. The semiconductor manufacturing method of claim 10, wherein, in the thermally deforming, a time for heating or cooling the first sub-area and a time for heating or cooling the second sub-area are set independently.

13. The semiconductor manufacturing method of claim 10, wherein, in the thermally deforming, a first time for heating or cooling the first sub-area is set to be greater than a second time for heating or cooling the second sub-area,
wherein at least some of the first time overlaps the second time.

14. The semiconductor manufacturing method of claim 1, wherein the stage comprises at least one adsorber for adsorbing the wafer to each area and is a chuck for chucking the wafer by being installed in a facility for performing the semiconductor process.

15. The semiconductor manufacturing method of claim 14, wherein, in the chucking of the wafer, an adsorption power of the adsorber increases as an area has a greater deviation of the wafer for a reference plane.

16. The semiconductor manufacturing method of claim 1, wherein the thermally deforming comprises a first thermal deformation for heating or cooling two areas of the plurality of areas of the stage spaced apart from each other in an angular direction at a temperature different from a temperature of two other areas of the plurality of areas of the stage.

17. The semiconductor manufacturing method of claim 16, wherein the thermally deforming further comprises a second thermal deformation for heating or cooling four areas of the plurality of areas of the stage that are spaced apart from one another in an angular direction at a temperature different from a temperature of four other areas of the plurality of areas of the stage.

18. The semiconductor manufacturing method of claim 17, wherein the thermally deforming further comprises the second thermal deformation for decreasing a deviation of a two-dimensional warpage of the wafer for a reference plane by heating or cooling at least one area of the plurality of areas of the stage and the plurality of areas of the stage are divided in a radial direction.

19. A semiconductor manufacturing method using warpage deformation, the semiconductor manufacturing method comprising:
thermally deforming a first area, having a crying warpage shape, of a wafer and a second area, having a smile warpage shape, of the wafer to be deformed into a warpage shape of an other area of the first area or second area by adjusting a temperature of each corresponding area of a stage where the wafer is mounted;
chucking the wafer when both the first area and the second area of the wafer have been deformed into the warpage shape of the other area of the first area or second area; and
performing a semiconductor process while the wafer is chucked.

20. A semiconductor manufacturing method using warpage deformation, the semiconductor manufacturing method comprising:
thermally deforming a first area, having a crying warpage shape, of a wafer and a second area, having a smile warpage shape, of the wafer to be deformed into a warpage shape of an other area of the first area or the second area by adjusting a temperature of each corresponding area of a stage where the wafer is mounted;
chucking the wafer when a deviation of a warpage of the wafer for a reference plane is less than a set value; and
performing a semiconductor process while the wafer is chucked.
